(19) United States
(12) Patent Application Publication
(10) Pub. No.: US 2011/0240117 A1
(43) Pub. Date: Oct. 6, 2011

(54) PHOTOVOLTAIC DEVICE WITH TRANSPARENT CONDUCTING LAYER

(76) Inventors: Yu Yang, Perrysburg, OH (US); Zhibo Zhao, Novi, MI (US); Benyamin Buller, Perrysburg, OH (US)

(21) Appl. No.: 13/078,697

(22) Filed: Apr. 1, 2011

Related U.S. Application Data
(60) Provisional application No. 61/320,534, filed on Apr. 2, 2010.

(51) Int. Cl. H01L 31/0224; H01L 31/18

(52) U.S. Cl. 136/256; 438/73; 257/E31.032

(57) ABSTRACT

A method of manufacturing structure may include forming a layer including cadmium and tin adjacent to a substrate, annealing the layer in a first annealing environment including a reducing agent, then annealing the layer in a second annealing environment including nitrogen.

### TECHNICAL FIELD

The present invention relates to photovoltaic devices and methods of production.

### BACKGROUND

Photovoltaic devices can include layers of materials, including, for example, a semiconductor layer adjacent to a transparent conductive oxide layer. The semiconductor layer can include a semiconductor window layer and a semiconductor absorber layer. Past photovoltaic devices have been inefficient at converting light energy to electrical power.

### DESCRIPTION OF DRAWINGS

FIG. 1 is a schematic of a structure having multiple layers.

FIG. 2 is a schematic of a photovoltaic device having multiple layers.

### DETAILED DESCRIPTION

Photovoltaic devices can include multiple layers formed on a substrate (or superstrate). For example, a photovoltaic device can include a barrier layer, a transparent conductive oxide (TCO) layer, a buffer layer, and a semiconductor layer formed in a stack on a substrate. Each layer may in turn include more than one layer or film. For example, the semiconductor layer can include a first film including a semiconductor window layer formed on the buffer layer and a second film including a semiconductor absorber layer formed on the semiconductor window layer. Additionally, each layer can cover all or a portion of the device and/or all or a portion of the layer or substrate underlying the layer. For example, a “layer” can mean any amount of any material that contacts all or a portion of a surface. An annealing step can be included in the process of manufacturing a photovoltaic device.

In one aspect, a method of manufacturing a multilayered structure can include forming a transparent conductive oxide layer adjacent to a substrate at a temperature between about 0 degrees C. and about 250 degrees C. The transparent conductive oxide layer can include cadmium and tin. The method can include annealing the transparent conductive oxide layer in first annealing environment. The first annealing environment can include a reducing agent at a temperature between about 400 degrees C. and about 800 degrees C. The method can include annealing the transparent conductive oxide layer in a second annealing environment. The second annealing environment can include nitrogen at a temperature between about 400 degrees C. and about 800 degrees C. The method can include forming a buffer layer adjacent to the transparent conductive oxide layer before annealing the structure. The buffer layer can include tin oxide. The method can include forming a semiconductor window layer adjacent to the buffer layer and a semiconductor absorber layer adjacent to the semiconductor absorber layer. The semiconductor absorber layer can include amorphous silicon.

The reducing agent can include forming gas. The reducing agent can include hydrogen. The reducing agent can include cadmium sulfide on a cover plate. The reducing agent can include nitrogen. The reducing agent can include natural gas. The reducing agent can include nitrogen and hydrogen. The second annealing environment can include oxygen. The second annealing environment can include air. Forming the transparent conductive oxide layer can include heating the substrate to a temperature between about 0 degrees C. and about 100 degrees C. Forming the transparent conductive oxide layer can include heating the substrate to a temperature between about 0 degrees C. and about 50 degrees C. Forming the transparent conductive oxide layer can include heating the substrate to a temperature between about 10 degrees C. and about 40 degrees C. The first annealing environment can be between about 500 degrees C. and about 700 degrees C. The first annealing environment can be between about 550 degrees C. and about 650 degrees C. The second annealing environment can be between about 500 degrees C. and about 700 degrees C. The second annealing environment can be between about 550 degrees C. and about 650 degrees C. Forming the transparent conductive oxide layer can include sputtering cadmium and tin adjacent to the substrate.

In one aspect, a method of increasing transmission of infrared light through an electrically conductive material can include forming a layer including cadmium and tin adjacent to a substrate at a temperature between about 0 degrees C. and about 250 degrees C. and annealing the layer in first annealing environment including a reducing agent and then in a second annealing environment including air to reduce the concentration of free carriers in the layer and to set the transmission percentage of light having a wavelength between about 1000 nm and about 1500 nm through the layer to above about 50%.

The reducing agent can include forming gas. The reducing agent can include hydrogen. The reducing agent can include natural gas. The reducing agent can include nitrogen. The reducing agent can include nitrogen and hydrogen. Forming the layer can include heating the substrate to a temperature between about 0 degrees C. and about 100 degrees C. The first annealing environment can be between about 500 degrees C. and about 700 degrees C. The second annealing environment can be between about 500 degrees C. and about 700 degrees C. Forming the layer can include sputtering cadmium and tin adjacent to the substrate. The transmission percentage of light having a wavelength between about 1000 nm and about 1500 nm through the can be is set to above about 75%.

In one aspect, a structure can include a substrate and an annealed transparent conductive oxide layer adjacent to the substrate. The transparent conductive oxide layer can include cadmium and tin. The annealed transparent conductive oxide layer can transmit over about 50% of light having a wavelength between about 1000 nm and about 1500 nm. The annealed transparent conductive oxide layer can have a sheet resistance between about 1 ohms/sq and about 30 ohms/sq.

The structure can include a semiconductor window layer adjacent to the annealed transparent conductive oxide layer and a semiconductor absorber layer adjacent to the semiconductor window layer. The semiconductor absorber layer can include amorphous silicon. The structure can include a back contact layer adjacent to the semiconductor absorber layer. The annealed transparent conductive oxide layer can transmit over about 60% of light having a wavelength between about 1000 nm and about 1500 nm. The annealed transparent conductive oxide layer can transmit over about 75% of light having a wavelength between about 1000 nm and about 1500 nm. The annealed transparent conductive oxide layer can transmit over about 80% of light having a wavelength between about 1000 nm and about 1500 nm. The annealed transparent conductive oxide layer can have a sheet resistance of between about 5 ohms/sq and about 25 ohms/sq. The annealed transparent conductive oxide layer can have a sheet resistance of between about 10 ohms/sq and about 20 ohms/sq.

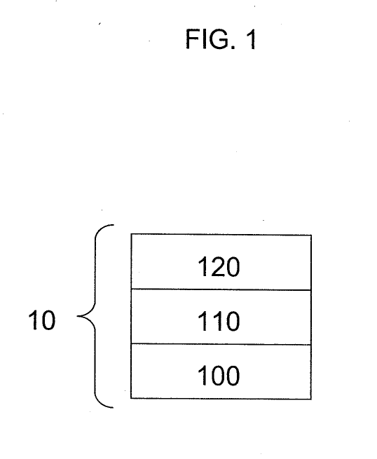

Referring to FIG. 1, by way of example, a transparent conductive oxide stack 10 may include a transparent conductive oxide (TCO layer 110 formed adjacent to barrier layer 100, adjacent to a substrate. The substrate can include glass or any other suitable material. The substrate can include glass. Barrier layer 100 can be incorporated between the substrate and TCO layer 110 to lessen diffusion of sodium or other contaminants from the substrate to the semiconductor layers, which could result in degradation and delamination. Barrier layer 100 can be transparent, thermally stable, with a reduced number of pin holes and having high sodium-blocking capability, and good adhesive properties. Barrier layer 100 may include any suitable barrier material, including, for example, a silicon oxide, aluminum-doped silicon oxide, boron-doped silicon oxide, phosphorous-doped silicon oxide, silicon nitride, aluminum-doped silicon nitride, boron-doped silicon nitride, phosphorous-doped silicon nitride, silicon oxide-nitride, titanium oxide, niobium oxide, tantalum oxide, aluminum oxide, zirconium oxide, tin oxide, or any combinations thereof. Barrier layer 100, along with TCO layer 110 and buffer layer 120 can be included in a TCO stack 10.

TCO layer 110 may include any suitable material or combination of materials, for example, cadmium and tin. TCO layer 110 can include cadmium stannate, which can function well in this capacity, as it exhibits high optical transmission and low electrical sheet resistance. TCO layer 110 can be transparent in the visible region (i.e., 400-850 nm) with a transmission percentage of more than about 80%. TCO layer 110 can be of any suitable thickness. For example, TCO layer 110 have a thickness of about 100 nm to about 1000 nm. Transparent conductive oxide stack 10 may also include a buffer layer 120 deposited on transparent conductive oxide layer 110. Buffer layer 120 can be smooth and can be formed between TCO layer 110 and a semiconductor window layer to reduce the likelihood of irregularities occurring during the formation of the semiconductor window layer. Buffer layer 120 can include any suitable material, such as tin oxide.

The layers included in TCO stack 10 can be manufactured using a variety of deposition techniques, including, for example, low pressure chemical vapor deposition, atmospheric pressure chemical vapor deposition, plasma-enhanced chemical vapor deposition, thermal chemical vapor deposition, DC or AC sputtering, spin-on deposition, or spray-pyrolysis. Each deposition layer can be of any suitable thickness, for example, in the range of about 10 to about 5000A. TCO layer 110 (e.g., cadmium and tin) can be formed at any suitable temperature. For example, TCO layer 110 can be formed at a temperature between about 0 degrees C. and about 250 degrees C. TCO layer 110 can be formed at a temperature between about 0 degrees C. and about 100 degrees C. TCO layer 110 can be formed at a temperature between about 0 degrees C. and about 50 degrees C. TCO layer 110 can be formed at a temperature between about 10 degrees C. and about 40 degrees C. TCO layer 110 can be formed at about room temperature.

Barrier layer 100, TCO layer 110, and/or buffer layer 120 can be formed by sputtering respective sputter targets including suitable sputter materials. For example, if TCO layer 110 includes cadmium stannate, the sputter target can include suitable amounts of cadmium and tin. The sputter target can be sputtered in an oxygen-containing environment.

A sputter target used for any of the above-described device layers can be manufactured by any suitable technique or combination of techniques. A sputter target can be manufactured as a single piece in any suitable shape. A sputter target can be a tube. A sputter target can be manufactured by casting a material into any suitable shape, such as a tube. A sputter target can be manufactured from more than one piece. The pieces can be manufactured in any suitable shape, such as sleeves, and can be joined or connected in any suitable manner or configuration. A sputter target can be manufactured by powder metallurgy, for example, from cadmium powder and tin powder. A sputter target can be formed by consolidating powder to form the target. The powder can be consolidated in any suitable process (e.g., pressing such as isostatic pressing) and in any suitable shape. The consolidating can occur at any suitable temperature. A sputter target can be formed from powder including more than one material powder. More than one powder can be present in stoichiometrically proper amounts.

Sputter targets (including rotary sputter targets) can include a sputter material used in connection with a backing material. The backing material can include stainless steel. The backing material can include a backing tube. The backing material can include a stainless steel backing tube. A sputter target can be manufactured by positioning wire including target material adjacent to a base. For example wire including target material can be wrapped around a base tube. The wire can include multiple materials present in stoichiometrically proper amounts. The base tube can be formed from a material that will not be sputtered. The wire can be pressed (e.g., by isostatic pressing). A sputter target can be manufactured by spraying a sputter material onto a base. Sputter material can be sprayed by any suitable spraying process, including thermal spraying and plasma spraying. The base onto which the target material is sprayed can be a tube.

In continuing reference to FIG. 1, following deposition, transparent conductive oxide stack 10 can undergo two separate annealing steps, which can allow TCO layer 110 to be electrically conductive and transparent in the infrared and near-infrared region. Devices including such a TCO layer 110 can include various electro-optic devices, such as electro-optic modulators, with working wavelength between about 1.3 μm to about 1.5 small band-gap semiconductor sensors and detectors, front contacts for small band-gap photovoltaic devices, and other devices needing visible-near-infrared transparency and low electrical sheet resistance.

In order to obtain a TCO layer 110 with TCO material having a low sheet resistance and a high transmission percentage in the near infrared and infrared ranges, TCO layer 110 can be annealed in multiple annealing environments. TCO stack 10 may undergo a first annealing step, in which TCO stack 10 is annealed in a reducing atmosphere and then a second annealing step, in which TCO stack 10 is annealed in a nitrogen-containing atmosphere. The reducing atmosphere of the first annealing environment can include any suitable reducing agent. Examples of possible reducing agents include cadmium sulfide used on a cover plate in the first annealing environment, a forming gas, hydrogen, nitrogen, and/or natural gas. Forming gas can include a mixture of hydrogen and nitrogen, including from about 1 mol. % to about 5.7 mol. % hydrogen. Forming gas can include about 3 parts hydrogen (e.g., H₂) to about 1 part nitrogen (e.g., N₂). Forming gas can include hydrogen gas and nitrogen gas. Forming gas can include a dissociated ammonia atmosphere. Natural gas can include methane and other alkanes (e.g., ethane, propane, butane, or pentane) and other components (e.g., carbon dioxide, nitrogen, helium, or hydrogen sulfide). The reducing agent can include hydrogen and nitrogen. The second annealing environment can include any suitable material or combination of materials, including nitrogen. The second annealing environment can include oxygen. The second annealing environment can include air.

The first and second annealing environments can be used at any suitable temperature. One or both of the annealing environments can be between about 400 degrees C. and about 800 degrees C. One or both of the annealing environments can be between about 500 degrees C. and about 700 degrees C. One or both of the annealing environments can be between about 550 degrees C. and about 650 degrees C. One or both of the annealing environments can be about 600 degrees C. Either one or both of the anneals can be at a temperature above about 40° C., above about 50° C., below about 65° C., or below about 75° C.

Following the first annealing step, TCO layer 110 may have a sheet resistance of between about 1 ohm/sq and about 15 ohm/sq. for example, between about 3 Ohm/sq, and about 7 Ohm/sq. After the first anneal, TCO layer 110 can have a transmission percentage of infrared and near-infrared light (e.g., light in the range of about 1000 nm wavelength to about 1500 nm) of less than about 75%, less than about 70%, less than about 60%, or less than about 50%. TCO layer 110 can be annealed in the second annealing environment. As a result, the multiple annealed TCO layer can have a transmission percentage of light having a wavelength between about 1000 nm and about 1500 nm of above about 50%, above about 60%, above about 75%, or above about 80%. The resulting TCO layer can have a sheet resistance of between about 1 ohm/sq and about 30 ohms/sq, between about 5 ohms/sq and about 25 ohms/sq, or between about 10 ohms/sq and about 20 ohms/sq.

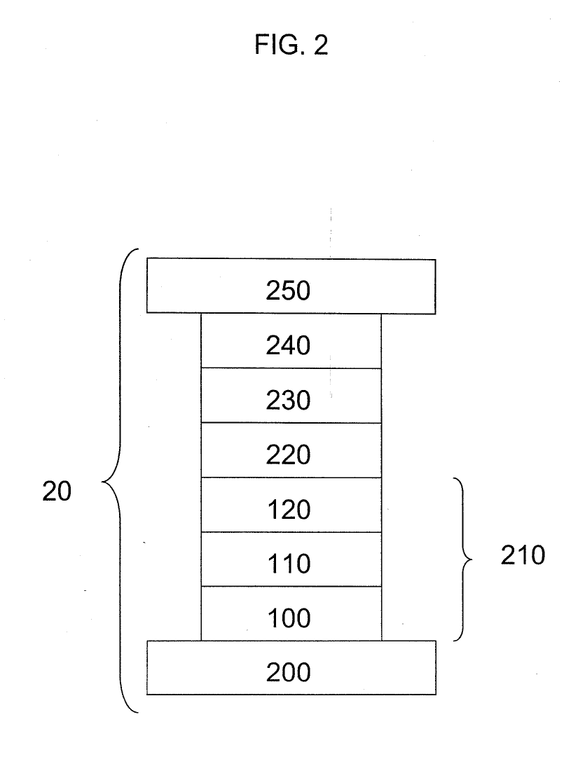

Each annealing step may occur under any suitable pressure, including, for example, under reduced pressure, under a low vacuum, or under about 0.01 Pa (10⁻⁴Torr). Each annealing step may occur for any suitable duration, including, for example, more than about 5 minutes, more than about 10 minutes, more than about 15 minutes, or less than about 25 minutes. In continuing reference to FIG. 2, a photovoltaic module 20, on glass substrate 200, may include a semiconductor window layer 220 and a semiconductor absorber layer 230 on annealed transparent conductive oxide stack 210. Semiconductor window layer 220 may include any suitable material, including, for example, a cadmium sulfide layer. Semiconductor absorber layer 230 may include any suitable material, including, for example, a cadmium telluride layer. Semiconductor absorber layer 230 can include silicon, including amorphous silicon. Semiconductor window layer 220 may be deposited directly onto annealed transparent conductive oxide stack 210, and semiconductor absorber layer 230 may be deposited thereon. Semiconductor window layer 220 and semiconductor absorber layer 230 may be deposited using any suitable deposition process, including, for example, vapor transport deposition. A back contact layer 240 may be deposited onto semiconductor absorber layer 230, and a back support 250 may be deposited thereon. Back contact layer 240 may include any suitable contact material, and may be deposited using any suitable means, including, for example, sputtering. Back support 250 may include any suitable material, including glass, for example, soda-lime glass.

The embodiments described above are offered by way of illustration and example. It should be understood that the examples provided above may be altered in certain respects and still remain within the scope of the claims. It should be appreciated that, while the invention has been described with reference to the above preferred embodiments, other embodiments are within the scope of the claims.

What is claimed is:

1. A method of manufacturing a multilayered structure, the method comprising:
forming a transparent conductive oxide layer comprising cadmium and tin adjacent to a substrate at a temperature between about 0 degrees C. and about 250 degrees C.;
annealing the transparent conductive oxide layer in first annealing environment comprising a reducing agent at a temperature between about 400 degrees C. and about 800 degrees C.; and
annealing the transparent conductive oxide layer in a second annealing environment comprising nitrogen at a temperature between about 400 degrees C. and about 800 degrees C.

2. The method of claim 1, further comprising forming a buffer layer adjacent to the transparent conductive oxide layer before annealing the structure, wherein the buffer layer comprises tin oxide.

3. The method of claim 2, further comprising forming a semiconductor window layer adjacent to the buffer layer and a semiconductor absorber layer adjacent to the semiconductor absorber layer, wherein the semiconductor absorber layer comprises amorphous silicon.

4. The method of claim 1, wherein the reducing agent comprises forming gas.

5. The method of claim 1, wherein the reducing agent comprises hydrogen.

6. The method of claim 5, wherein the reducing agent comprises cadmium sulfide on a cover plate.

7. The method of claim 1, wherein the reducing agent comprises natural gas.

8. The method of claim 1, wherein the reducing agent comprises nitrogen.

9. The method of claim 1, wherein the reducing agent comprises nitrogen and hydrogen.

10. The method of claim 1, wherein the second annealing environment further comprises oxygen.

11. The method of claim 9, wherein the second annealing environment comprises air.

12. The method of claim 1, wherein forming the transparent conductive oxide layer comprises heating the substrate to a temperature between about 0 degrees C. and about 100 degrees C.

13. The method of claim 1, wherein forming the transparent conductive oxide layer comprises heating the substrate to a temperature between about 0 degrees C. and about 50 degrees C.

14. The method of claim 1, wherein forming the transparent conductive oxide layer comprises heating the substrate to a temperature between about 10 degrees C. and about 40 degrees C.

15. The method of claim 1, wherein the first annealing environment is between about 500 degrees C. and about 700 degrees C.

16. The method of claim 1, wherein the first annealing environment is between about 550 degrees C. and about 650 degrees C.

17. The method of claim 1, wherein the second annealing environment is between about 500 degrees C. and about 700 degrees C.

18. The method of claim 1, wherein the second annealing environment is between about 550 degrees C. and about 650 degrees C.

19. The method of claim 1, wherein forming the transparent conductive oxide layer comprises sputtering cadmium and tin adjacent to the substrate.

20. A method of increasing transmission of infrared light through an electrically conductive material comprising:
forming a layer comprising cadmium and tin adjacent to a substrate at a temperature between about 0 degrees C. and about 250 degrees C.; and
annealing the layer in first annealing environment comprising a reducing agent and then in a second annealing environment comprising air to reduce the concentration of free carriers in the layer and to set the transmission percentage of light having a wavelength between about 1000 nm and about 1500 nm through the layer to above about 50%.

21. The method of claim 20, wherein the reducing agent comprises forming gas.

22. The method of claim 20, wherein the reducing agent comprises hydrogen.

23. The method of claim 22, wherein the reducing agent comprises natural gas.

24. The method of claim 20, wherein the reducing agent comprises nitrogen.

25. The method of claim 1, wherein the reducing agent comprises nitrogen and hydrogen.

26. The method of claim 1, wherein forming the layer comprises heating the substrate to a temperature between about 0 degrees C. and about 100 degrees C.

27. The method of claim 1, wherein the first annealing environment is between about 500 degrees C. and about 700 degrees C.

28. The method of claim 1, wherein the second annealing environment is between about 500 degrees C. and about 700 degrees C.

29. The method of claim 1, wherein forming the layer comprises sputtering cadmium and tin adjacent to the substrate.

30. The method of claim 20, wherein the transmission percentage of light having a wavelength between about 1000 nm and about 1500 nm through the layer is set to above about 75%.

31. A structure comprising:
a substrate; and
an annealed transparent conductive oxide layer adjacent to the substrate, wherein the transparent conductive oxide layer comprises cadmium and tin, transmits over about 50% of light having a wavelength between about 1000 nm and about 1500 nm, and has a sheet resistance between about 1 ohms/sq and about 30 ohms/sq.

32. The structure of claim 31, further comprising a semiconductor window layer adjacent to the annealed transparent conductive oxide layer and a semiconductor absorber layer adjacent to the semiconductor window layer.

33. The structure of claim 32, wherein the semiconductor absorber layer comprises amorphous silicon.

34. The structure of claim 32, further comprising a back contact layer adjacent to the semiconductor absorber layer.

35. The structure of claim 31, wherein the annealed transparent conductive oxide layer transmits over about 60% of light having a wavelength between about 1000 nm and about 1500 nm.

36. The structure of claim 31, wherein the annealed transparent conductive oxide layer transmits over about 75% of light having a wavelength between about 1000 nm and about 1500 nm.

37. The structure of claim 31, wherein the annealed transparent conductive oxide layer transmits over about 80% of light having a wavelength between about 1000 nm and about 1500 nm.

38. The structure of claim 31, wherein the annealed transparent conductive oxide layer has a sheet resistance of between about 5 ohms/sq and about 25 ohms/sq.

39. The structure of claim 31, wherein the annealed transparent conductive oxide layer has a sheet resistance of between about 10 ohms/sq and about 20 ohms/sq.
